(19) United States
(12) Patent Application Publication
(10) Pub. No.: US 2010/0060323 A1
(43) Pub. Date: Mar. 11, 2010

(54) TEST CIRCUIT AND TEST METHOD

(75) Inventor: Yoshikazu Sumi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/585,116

(22) Filed: Sep. 3, 2009

(30) Foreign Application Priority Data
Sep. 8, 2008 (JP) 2008-229964

(51) Int. Cl. H03K 5/00

(52) U.S. Cl. 327/50

(57) ABSTRACT

A test circuit with which the cost for checking the duty ratio of a clock signal is restrained. A sampling timing generating circuit, to which the measurement-target clock signal MCK is input, outputs first and second sampling trigger signals to A sample-and-hold circuit 102 respective prescribed timings before and after a timing that is one-half period of the measurement-target clock signal after a first edge of the measurement-target clock signal. The sample-and-hold circuit samples and holds the measurement-target clock signal in correspondence with respective ones of the first and second sampling trigger signals. The sample-and-hold circuit forms all or part of a scan path and outputs a signal, which is being held for checking the duty ratio, from a scan output terminal in response to a scan clock signal.

### REFERENCE TO RELATED APPLICATION

This application is based upon and claims the benefit of the priority of Japanese patent application No. 2008-229964, filed on Sep. 8, 2008, the disclosure of which is incorporated herein in its entirety by reference thereto.

### TECHNICAL FIELD

This invention relates to a test circuit and test method. More particularly, the invention relates to a test technique for checking the duty ratio of a clock signal in an LSI chip.

### BACKGROUND

With the use of microfabrication and low power in LSI chips, the duty ratio of a clock signal within an LSI chip has become one important quality requirement for preventing malfunction. For example, with the SF14 interface standard for high-speed serial communication between LSI chips, a clock signal used within an LSI chip is output as a reference clock signal for communication between LSI chips. For this reason, a high quality is required with regard to the duty ratio of the clock signal within the LSI chip and it is required that the duty ratio of the clock signal be tested at the time of the LSI shipping test.

With regard to such a test technique for checking the duty ratio of a clock signal, Patent Document 1, for example, describes a test circuit and test method for testing the duty ratio of an oscillation circuit incorporated in a semiconductor integrated circuit. The test circuit incorporates a delay element, the amount of delay of which can be controlled, inside an LSI chip. The timing difference between a clock signal delayed by one period by the delay element and the original clock signal is detected a plurality of times. This is counted by a counter circuit to thereby detect clock signal jitter. The duty ratio is calculated based upon the value of the result of measurement.

### [Patent Document 1]

Japanese Patent Kokai Publication No. JP2003-121505A

### SUMMARY

The entire disclosure of the above Patent Document 1 is incorporated herein by reference thereto.

The analysis set forth below is given in this invention.

With the test circuit of Patent Document 1, the amount of delay must be adjusted externally, the counter value acquired from the counter circuit and the duty ratio computed. The test conducted at shipping time of the LSI chip therefore takes a long time. In addition, it is required that the LSI chip and the test equipment have a function for adjusting amount of delay from outside the LSI chip and a function for reading out the count value from the counter circuit. This results in additional cost for development. Furthermore, not only is the LSI chip required to have a delay element but special-purpose circuitry such as the counter circuit also is required. As a consequence, checking the duty ratio of the clock signal involves a high cost.

According to a first aspect of the present invention there is provided a test circuit comprising: a sampling timing generating circuit, to which a measurement-target clock signal is input, and outputs first and second sampling trigger signals at respective timings corresponding to times before and after a timing that is one-half period of the measurement-target clock signal after a first edge of the measurement-target clock signal; and a sample-and-hold circuit that samples and holds the measurement-target clock signal at timings corresponding to the respective first and second sampling trigger signals.

According to a second aspect of the present invention there is provided a test method comprising: inputting a measurement-target clock signal; and sampling and holding the measurement-target clock signal at respective prescribed timings before and after a timing that is one-half period of the measurement-target clock signal after a first edge of the measurement-target clock signal.

The meritorious effects of the present invention are summarized as follows.

In accordance with the present invention, the cost for checking the duty ratio of the clock signal can be reduced since the function for checking the duty ratio of the clock signal in the LSI chip is configured within the LSI chip.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a diagram illustrating the configuration of a test circuit according to the present invention;

FIG. 2 is a circuit diagram of a test circuit according to a first exemplary embodiment of the present invention;

FIG. 3 is a timing chart of the test circuit according to the first exemplary embodiment;

FIG. 4 is a circuit diagram of a test circuit according to a second exemplary embodiment of the present invention;

FIG. 5 is a timing chart of the test circuit according to the second exemplary embodiment;

FIG. 6 is a circuit diagram of a test circuit according to a third exemplary embodiment of the present invention;

FIG. 7 is an equivalent circuit in a sampling timing generating circuit according to the third exemplary embodiment;

FIG. 8 is another equivalent circuit in a sampling timing generating circuit according to the third exemplary embodiment;

FIGS. 9A to 9D are timing charts of a test circuit according to the third exemplary embodiment;

FIG. 10 is a circuit diagram of a test circuit according to a fourth exemplary embodiment of the present invention; and

FIG. 11 is a circuit diagram of a test circuit according to a fifth exemplary embodiment of the present invention.

### PREFERRED MODES

In the present invention the following preferred modes are possible.

### Mode 1: as Set Forth as the First Aspect.

### Mode 2:

The sampling timing generating circuit may output third and fourth sampling trigger signals at respective prescribed timings before and after the first edge; and the sample-and-hold circuit samples and holds the measurement-target clock signal MCK further in correspondence with respective ones of the third and fourth sampling trigger signals.

### Mode 3:

The sample-and-hold circuit may be included in a scan path.

### Mode 4:

The sample-and-hold circuit may include four registers that construct a scan-path register; sampling values, which have been sampled at the first to fourth sampling trigger signals, being stored in respective ones of the corresponding registers.

### Mode 5:

The sampling timing generating circuit may receive the measurement-target clock signal MCK as an input, generate a signal having a frequency that is double that of the measurement-target clock signal MCK, and generate the first to fourth sampling trigger signals based upon the generated signal having double the frequency.

### Mode 6:

The sampling timing generating circuit may include a PLL circuit for receiving the measurement-target clock signal MCK as an input and generating the signal having double the frequency; a delay circuit for delaying an output signal from the PLL circuit; and a frequency dividing circuit for frequency-dividing the output signal from the PLL circuit and applying a prescribed delay; the sampling timing generating circuit generating the first and third sampling trigger signals based upon the output signal from the PLL circuit and generates the second and fourth sampling trigger signals based upon an output signal from the delay circuit; and the sample-and-hold circuit samples and holds the measurement-target clock signal MCK in correspondence with respective ones of the first and second sampling trigger signals when an output signal from the frequency dividing circuit is at a first logic level, and samples and holds the measurement-target clock signal MCK in correspondence with respective ones of the third and fourth sampling trigger signals when the output signal from the frequency dividing circuit is at a second logic level.

### Mode 7:

The sampling timing generating circuit may comprise a multistage delay circuit that delays the measurement-target clock signal MCK received as an input thereto; the first to fourth sampling trigger signals being output from respective ones of prescribed positions in the delay circuit.

### Mode 8:

The sampling timing generating circuit may comprise two sets of cascade-connected multistage delay circuits for delaying the measurement-target clock signal MCK received as an input thereto; and the two sets of delay circuits are arranged in such a manner that the delay circuits in the cascade relationship are mutually interchangeable, the first and second sampling trigger signals are output from respective ones of prescribed positions in one of the delay circuits and the third and fourth sampling trigger signals are output from respective ones of prescribed positions in the other of the delay circuits.

### Mode 9:

The sample-and-hold circuit may be adapted so as to make it possible to store an output of a user circuit in the register in response to a user clock signal.

### Mode 10:

The circuit according to modes 1 to 9 may further comprise a differential receiving circuit for converting differential signals into a single-phase signal, wherein the single-phase signal obtained by the conversion is input as the measurement-target clock signal MCK. Mode 11:

A semiconductor device having the test circuit set forth any one of modes 1 to 10.

### Mode 12:

A method of testing a semiconductor device as set forth in the second aspect.

### Mode 13:

The method according to mode 12 may further comprise a step of outputting the sampled-and-held signal via a scan path.

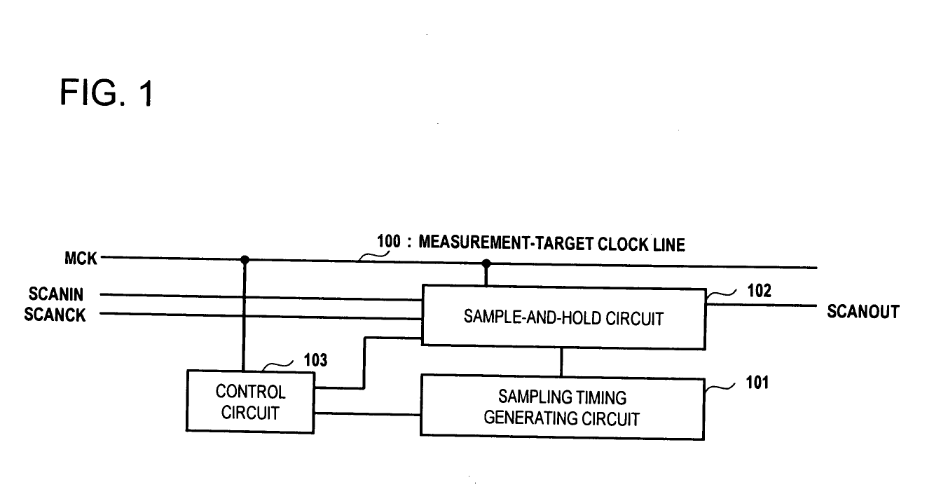

FIG. 1 is a diagram illustrating the configuration of a test circuit according to the present invention. As shown in FIG. 1, the test circuit includes a sample-and-hold circuit 102 for sampling and holding a measurement-target clock signal MCK in a measurement-target clock line 100; a sampling timing generating circuit 101 for generating sampling timing signals of the sample-and-hold circuit 102; and a control circuit 103 for controlling these two circuits and exercising control so as to output result of measurement from a scan output SCANOUT.

The sampling timing generating circuit 101, to which the measurement-target clock signal MCK is input, outputs first and second sampling trigger signals to the sample-and-hold circuit 102 at respective prescribed timings before and after a timing that is one-half period of the measurement-target clock signal MCK after a first edge of the measurement-target clock signal MCK.

The sample-and-hold circuit 102 samples and holds the measurement-target clock signal MCK in correspondence with respective ones of the first and second sampling trigger signals. The sample-and-hold circuit 102 forms all or part of a scan path and outputs a signal, which is being held for checking the duty ratio, from the scan output SCANOUT in response to a scan clock signal SCANCK. Under the control of the control circuit 103, the sample-and-hold circuit 102 functions also as an ordinary scan path for outputting a signal, which enters from a scan input SCANIN, from the scan output SCANOUT in response to the scan clock signal SCANCK.

Further, it may be so arranged that the sampling timing generating circuit 101 outputs third and fourth sampling trigger signals at respective prescribed timings before and after the first edge, and the sample-and-hold circuit 102 samples and holds the measurement-target clock signal MCK further in correspondence with respective ones of the third and fourth sampling trigger signals.

It may be so arranged that the sample-and-hold circuit 102 includes four registers that construct a scan-path register, wherein sampling values that have been sampled at the first to fourth sampling trigger signals are stored in respective ones of the corresponding registers.

It may be so arranged that the sampling timing generating circuit 101 receives the measurement-target clock signal MCK as an input, generates a signal having a frequency that is double that of the measurement-target clock signal MCK and generates the first to fourth sampling trigger signals based upon the generated signal having double the frequency.

It may be so arranged that the sampling timing generating circuit 101 includes a PLL circuit for receiving the measurement-target clock signal MCK as an input and generating the signal having double the frequency; a delay circuit for delaying an output signal from the PLL circuit; and a frequency dividing circuit for frequency-dividing the output signal from the PLL circuit and applying a prescribed delay; wherein the sampling timing generating circuit 101 generates the first and third sampling trigger signals based upon the output signal from the PLL circuit and generates the second and fourth sampling trigger signals based upon an output signal from the delay circuit; and the sample-and-hold circuit 102 samples and holds the measurement-target clock signal MCK in correspondence with respective ones of the first and second sampling trigger signals when an output signal from the frequency dividing circuit is at a first logic level, and samples and holds the measurement-target clock signal MCK in correspondence with respective ones of the third and fourth sampling trigger signals when the output signal from the frequency dividing circuit is at a second logic level.

It may be so arranged that the sampling timing generating circuit 101 comprises a multistage delay circuit for delaying the measurement-target clock signal MCK received as an input thereto, the first to fourth sampling trigger signals being output from respective ones of prescribed positions in the delay circuit.

It may be so arranged that the sampling timing generating circuit 101 comprises two sets of cascade-connected multistage delay circuits for delaying the measurement-target clock signal MCK received as an input thereto; wherein the two sets of delay circuits are arranged in such a manner that the delay circuits in the cascade relationship are mutually interchangeable, the first and second sampling trigger signals are output from respective ones of prescribed positions in one of the delay circuits and the third and fourth sampling trigger signals are output from respective ones of prescribed positions in the other of the delay circuits.

The sample-and-hold circuit 102 may be adapted so as to make it possible to store an output of a user circuit in the register in response to a user clock signal.

It may be so arranged that the test circuit further includes a differential receiving circuit for converting differential signals into a single-phase signal, wherein the single-phase signal obtained by the conversion is input as the measurement-target clock signal MCK.

It may be so arranged that a semiconductor device has the test circuit described above.

In accordance with the test circuit described above, the state values of the rising and falling edges of a clock signal are sampled and held using a scan-path register, which forms all or part of a scan path, and a circuit for generating sampling timing, and an expected value of duty ratio is determined by an externally connected tester in a manner similar to an ordinary scan result. Accordingly, since the expected value of duty ratio can be determined at the same time as another scan test, there is no increase in test time and test time is made very short.

Further, a test to check the duty ratio of a clock signal merely involves checking by a tester to determine that there is agreement with the expected value, this being performed as part of a scan test; no special equipment is necessary to make the check. Furthermore, the check can be made satisfactorily even with an inexpensive tester that can only handle low-speed clock signals. There is no additional investment needed for special equipment and a tester.

Further, the test circuit does not require a function for adjusting delay externally and is constituted by a plurality of scan-path registers, a circuit for generating sampling timing and a control circuit. As a result, there is no increase in the size of the test circuit.

Preferred exemplary embodiments of the present invention will now be described in detail with reference to the drawings.

### First Exemplary Embodiment

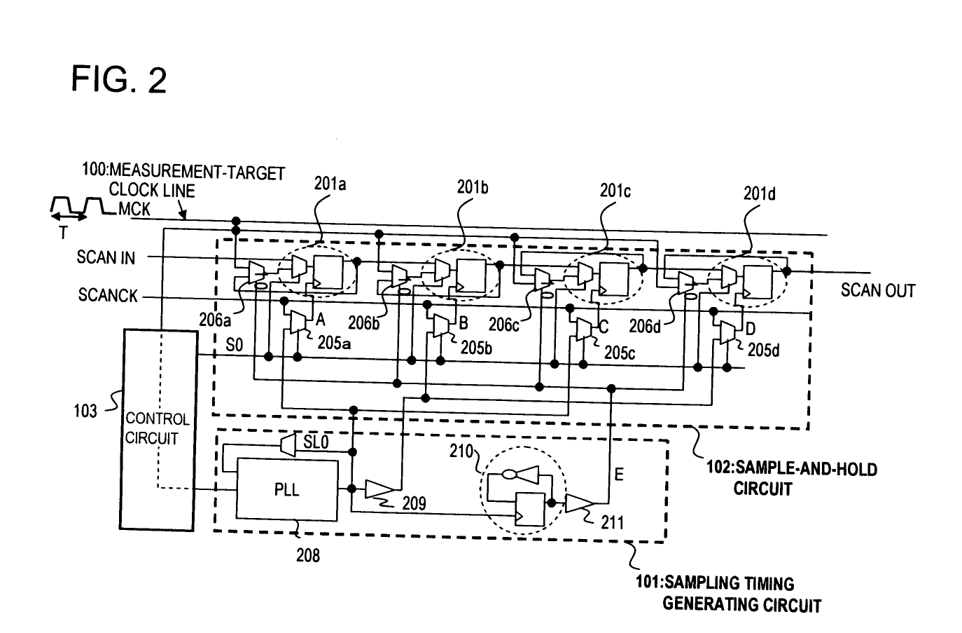

FIG. 2 is a circuit diagram of a test circuit according to a first exemplary embodiment of the present invention. Components in FIG. 2 identical with those shown in FIG. 1 are designated by like reference characters. The test circuit according to the first exemplary embodiment uses a PLL 208 as the sampling timing generating circuit 101.

The sampling timing generating circuit 101 includes the PLL 208, which is for phase adjustment and is capable of outputting a signal having a period that is one-half that of the measurement-target clock signal MCK; a delay gate 209 for adjusting the delay of the output signal from the PLL 208; a frequency dividing circuit 210 for generating a signal that is the result of frequency-dividing the output signal of the PLL 208 by two; and a delay gate 211 for adjusting the delay of the output signal from the frequency dividing circuit 210.

The sample-and-hold circuit 102 includes scan flip-flops (referred to as “MUXSCANFF” below) 201a, 201b, 201c, 201d having multiplexers for changing over between a path at the time of a scan-shift operation and a path at the time of a sampling operation; multiplexers 205a, 205b, 205c, 205d connected to clock terminals of the four MUXSCANFFs for changing over between a timing signal at the time of the scan-shift operation and a timing signal at the time of the sampling operation; and multiplexers 206a, 206b, 206c, 206d for changing over between a signal sampled at the timing of the sampling operation and signals held by the respective MUXSCANFFs.

The multiplexers 206a, 206b operate so as to select the measurement-target clock signal MCK, which is the signal to be sampled, when the logic level of a selection signal E that is output by the delay gate 211 is “1”, and select signals, which are being held by the respective MUXSCANFFs 201a, 201b, when the logic level of a selection signal E is “0”. Further, the multiplexers 206c, 206d operate converse to the multiplexers 206a, 206b so as to select the signals held in the respective MUXSCANFFs 201c, 201d when the logic level of a selection signal E that is “1”, and select the measurement-target clock signal MCK when the logic level of a selection signal E is “0”.

The MUXSCANFFs 201a, 201b, 201c and 201d form a scan chain as all or part of a scan path and, along with the multiplexers 205a, 205b, 205c and 205d, are controlled by a scan selection signal S0 from the control circuit 103 for performing a scan-shift operation in accordance with the low-speed scan clock signal SCANCK and outputting the result of sampling from the scan output SCANOUT.

Let T represent the period of the measurement-target clock signal MCK, and assume that the required range for the duty ratio Δ (%) of the measurement-target clock signal MCK is a <Δ<b. In this case, assume that the path on which the reference clock signal of the PLL 208 enters from the measurement-target clock line 100 via the control circuit 103 sustains a delay time of a·T/100. The clock output of the PLL 208 is supplied to each of the multiplexers 205a, 205c as the clock signal at the time of the sampling operation of the MUXSCANFFs 201a, 201c. The delay on the path that connects the clock output of the PLL 208 to the clock inputs of the MUXSCANFFs 201a, 201c through the multiplexers 205a, 205c is designed so as to be equal to the delay on the loop-back path of the PLL 208. To achieve this, a circuit SL0 corresponding to the multiplexers 205a, 205c is inserted into the loop-back path of the PLL 208, by way of example.

In the required range a <Δ<b of the duty ratio indicated above, an adjustment is applied using the delay gate 209 in such a manner that the delay time of the path that connects the clock output of the PLL 208 to the clock inputs of the MUXSCANFFs 201b, 201d through the multiplexers 205b, 205d, respectively, will be longer by (b−a)·T/100 than the delay time of the path that connects the clock output of the PLL 208 to the clock inputs of the MUXSCANFFs 201a, 201c through the multiplexers 205a, 205c, respectively.

The output of the frequency dividing circuit 210, which frequency-divides the clock output of the PLL 208 by two, is adopted as the selection control signal E of the multiplexers 206a, 206b, 206c and 206d. The delay time of the selection control signal E is adjusted by connecting the delay gate 211 to the output of the frequency dividing circuit 210 so that the delay time from the output of the frequency dividing circuit 210 to the multiplexers 206a, 206b, 206c and 206d will be longer by T/2 than the delay time of the path from the clock output of the PLL 208 to the clock inputs of the MUXSCANFFs 201a, 201c through the multiplexers 205a, 205c, respectively.

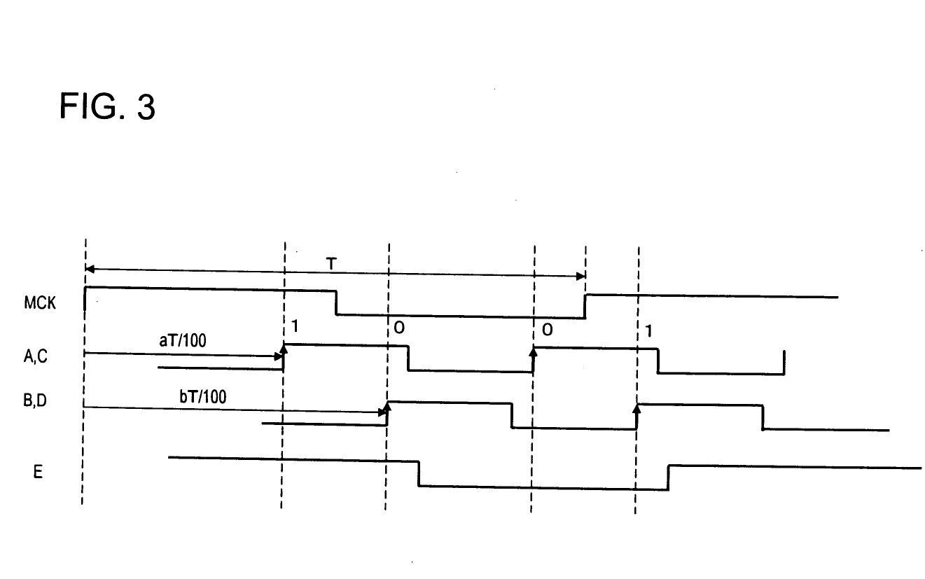

The operation of the test circuit will be described on the assumption that the period of the measurement-target clock signal MCK is T and that the required range for the duty ratio Δ (%) of the measurement-target clock signal MCK is a <Δ<b, as indicated above, with the circuit being constructed based upon this required range for the duty ratio. The timing chart in such case is as illustrated in FIG. 3. Based upon the operating principle of the PLL, the rising edge of clock signals A, C of the MUXSCANFFs 201a, 201c coincides with the rising edge of the reference clock of the PLL 208. In other words, frequency-doubled clock signals A, C, the phase of which lags behind the edge of the measurement-target clock signal MCK by the delay time a·T/100 of the path that connects the measurement-target clock line 100 to the reference clock of the PLL 208 via the control circuit 103, are input to the MUXSCANFFs 201a, 201c.

Further, with regard to the MUXSCANFFs 201b, 201d, frequency-doubled clock signals B, D, the phase of which lags behind the clock edge of the MUXSCANFFs 201a, 201c by (b−a)·T/100, are input. In other words, frequency-doubled clock signals B, D, the phase of which lags behind the edge of the measurement-target clock signal MCK by (b−a)·T/100+a·T/100=b·T/100, are input to the MUXSCANFFs 201b, 201d.

The falling edge of the measurement-target clock signal MCK will reside between a·T/100 and b·T/100 if it is normal. Since each MUXSCANFF is operated by the clock signal that is doubled with respect to the measurement-target clock signal MCK, each MUXSCANFF has an opportunity to perform sampling twice per one period of the measurement-target clock signal MCK. Accordingly, the delay gate 211 delays the frequency-divided signal from the frequency dividing circuit 210 by T/2 with respect to the clock edge of the MUXSCANFFs 201a, 201c and outputs the delayed signal as the selection control signal E of the multiplexers 206a, 206b, 206c, 206d.

The two multiplexers 206a, 206b select the measurement-target clock signal MCK when the selection signal E is at logic level “1”, and the two multiplexers 206c, 206d select the measurement-target clock signal MCK when the selection signal E is at logic level “0”. Accordingly, the MUXSCANFFs 201a, 201b are capable of detecting a shift in the phase of the falling edge of the measurement-target clock signal MCK, and the MUXSCANFFs 201c, 201d are capable of detecting a shift in the phase of the rising edge of the measurement-target clock signal MCK. For example, if the duty ratio of the measurement-target clock signal MCK is smaller than the required limit a, then the falling edge of the measurement-target clock signal MCK shifts to the left side of the point in time a·T/100, the MUXSCANFFs 201a, 201b each sample the “0” level of the signal MCK and output the logic values “00” from the scan output SCANOUT. The result will be non-agreement with the expected value in a tester screening test and the chip can be screened out as being one that is out of spec.

The MUXSCANFFs, multiplexers, delay gates and PLL used in this specification are basic elements in LSI chip design and scan test design and the conventional LSI chip design methods can be used in the designing thereof. This means that almost no additional cost is entailed in terms of implementing the test function. Further, the test for checking the duty ratio merely involves checking by a tester to determine agreement with the expected value, this being performed as part of a scan test; no special equipment is necessary to make the check. This means that there is no additional cost. Furthermore, the result can be checked satisfactorily even with an inexpensive tester that can only deal with low-speed clock signals. This makes it possible to hold down spending for testers.

Further, since a PLL is used as the sampling timing generating circuit, an increase in the size of the circuitry can be restrained if consideration is given to provide commonality with internal use within the LSI chip at the initial stage of LSI chip design.

### Second Exemplary Embodiment

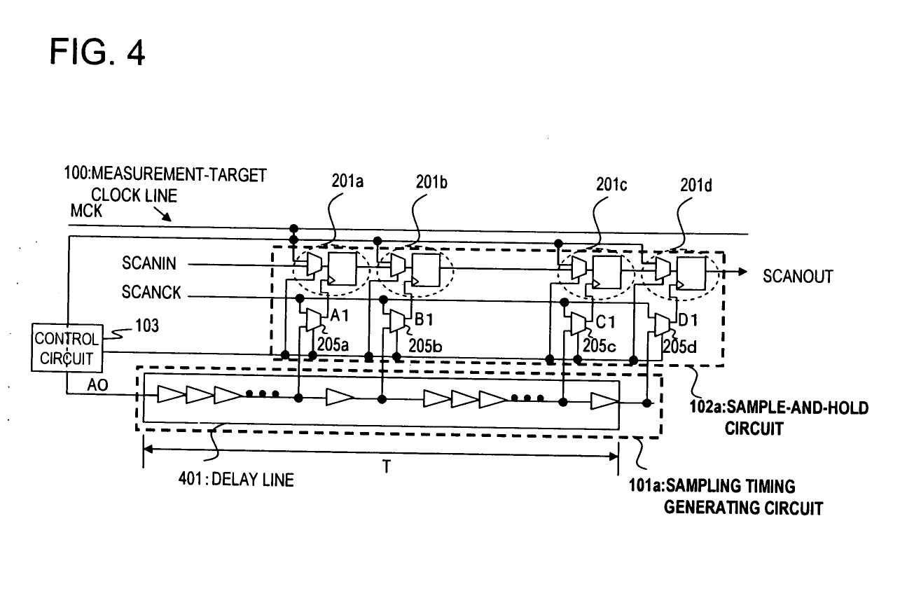

FIG. 4 is a circuit diagram of a test circuit according to a second exemplary embodiment of the present invention. Components in FIG. 4 identical with those shown in FIG. 2 are designated by like reference characters and need not be described again. The test circuit according to the second exemplary embodiment includes a sampling timing generating circuit 101a equipped with a delay line 401. Gates constituting the delay line 401 are not limited to a delay gate and may be any gates, such as buffer gates or inverter gates, as long as delay can be controlled. The delay line 401 is obtained by connecting these gates in series.

A sample-and-hold circuit 102a includes the four MUXSCANFFs 201a, 201b, 201c, 201d in a manner similar to the first exemplary embodiment. This exemplary embodiment differs from the first exemplary embodiment in that the connection destination of the path at the time of the sampling operation of the multiplexers constituting the MUXSCANFFs is the measurement-target clock line 100 in direct fashion. Further, the multiplexers 206a, 206b, 206c, 206d and frequency dividing circuit 210 in FIG. 2 are unnecessary.

The input of the delay line 401 is connected to the measurement-target clock line 100 via the control circuit 103. If T represents the period of the measurement-target clock signal MCK and we assume that the required range for the duty ratio Δ (%) of the measurement-target clock signal MCK is a <Δ<b, then T will be the delay time from the input of the delay line 401 to the output of the final stage of the delay line. The path delay time is designed in such a manner that delay time (delay time of a signal D1) on the path that connects the measurement-target clock line 100 to the clock input terminal of the MUXSCANFF 201d through the control circuit 103 and further through the final stage of the delay line 401 will become bT/100+T/2. Further, the number of connected gates in the delay line 401 is selected in such a manner that delay time (delay time of a signal C1) until the measurement-target clock signal MCK arrives at the clock terminal of the MUXSCANFF 201c will be aT/100+T/2, delay time (delay time of a signal B1) until the measurement-target clock signal MCK arrives at the clock terminal of the MUXSCANFF 201b will be bT/100, and delay time (delay time of a signal A1) until the measurement-target clock signal MCK arrives at the clock terminal of the MUXSCANFF 201a will be aT/100.

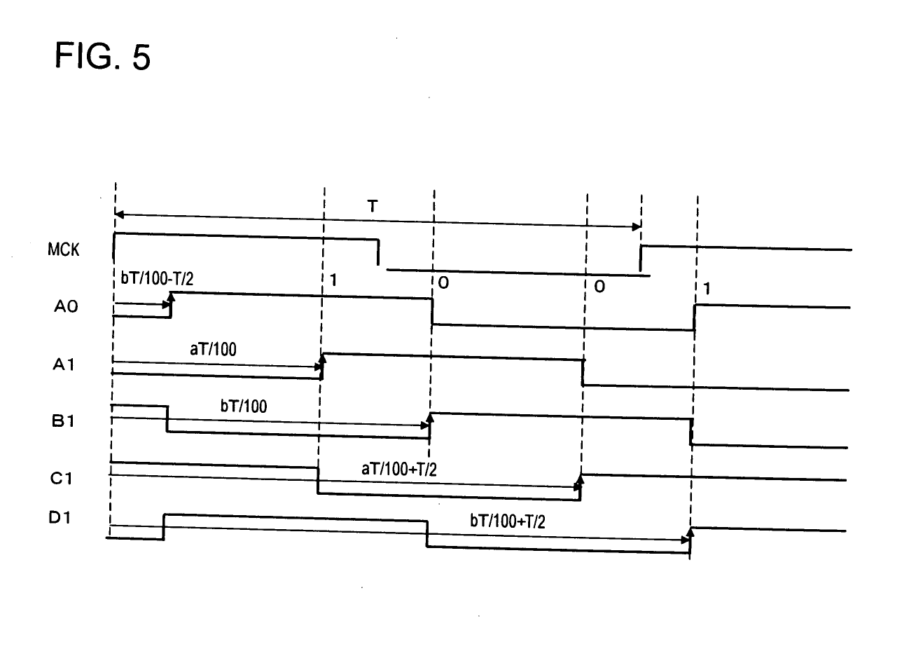

The operation of the test circuit will be described on the assumption that the period of the measurement-target clock signal MCK is T and that the required range for the duty ratio Δ (%) of the measurement-target clock signal MCK is a <Δ<b, with the circuit being constructed based upon this required range for the duty ratio. The timing chart in such case is as illustrated in FIG. 5. In a case where the measurement-target clock signal MCK is normal, meaning that it meets the desired specifications, the falling edge of the measurement-target clock signal MCK will reside between aT/100 and bT/100, and the rising edge of the measurement-target clock signal MCK will reside between aT/100+T/2 and bT/100+T/2. In this case, the MUXSCANFFs 201a, 201b, 201c, 201d sample and hold the measurement-target clock signal MCK at the timings of the rising edges of the signals A1, B1, C1, D1, respectively, and output the sampled signal from the scan output SCANOUT as logic levels “1001”, respectively.

By contrast, in a case where the duty ratio of the measurement-target clock signal MCK is smaller than the required limit a, the falling edge of the measurement-target clock signal MCK shifts to the left side of the point in time a·T/100. Accordingly, the MUXSCANFFs 201a, 201b each sample the “0” level of the signal MCK and they output the logic levels “00” from the scan output SCANOUT. The result will be non-agreement with the expected value in a tester screening test and the chip can be screened out as being one that is out of spec.

The test circuit of the second exemplary embodiment is applicable even in the case of an LSI chip not equipped with a PLL.

### Third Exemplary Embodiment

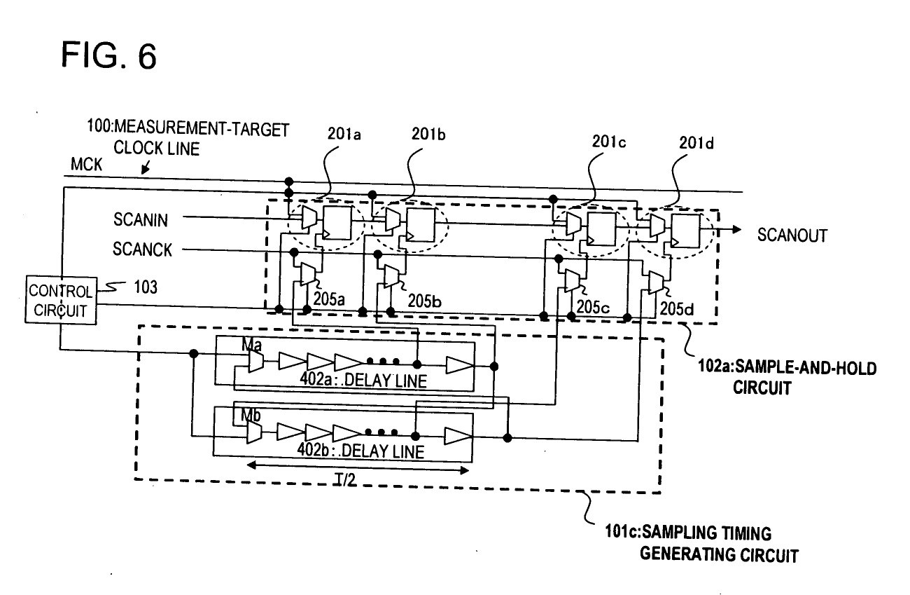

FIG. 6 is a circuit diagram of a test circuit according to a third exemplary embodiment of the present invention. Components in FIG. 6 identical with those shown in FIG. 4 are designated by like reference characters and need not be described again. This test circuit has a sampling timing generating circuit 101c. The sample-and-hold circuit 102a is identical with that of the second exemplary embodiment.

The sampling timing generating circuit 101c includes delay lines 402a, 402b having multiplexers Ma, Mb, respectively, as an input stage, and has a delay time up to the final stage being T/2. Which of the delay lines 402a, 402b first picks up the clock signal that is input to the sampling timing generating circuit 101c is selected by the initial-stage multiplexers Ma, Mb. Further, the delay time of the overall sampling timing generating circuit is assumed to be T, the same as in the second exemplary embodiment. Furthermore, timing design is such that the delay times on the paths that connect the measurement-target clock line 100 to the clock terminals of the MUXSCANFFs of the sample-and-hold circuit 102a through the control circuit 103 and sampling timing generating circuit 101c will be the same as in the second exemplary embodiment in accordance with the timing chart of FIG. 5.

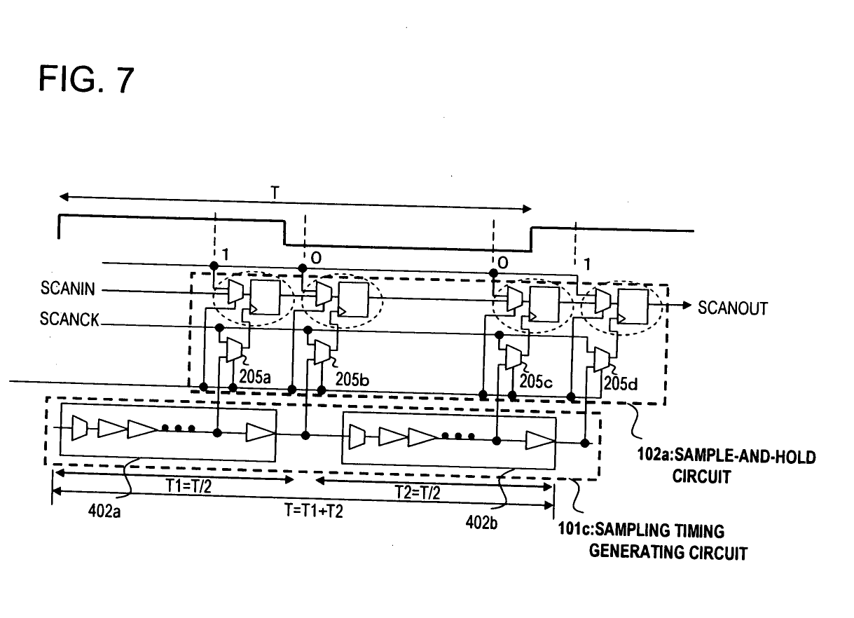

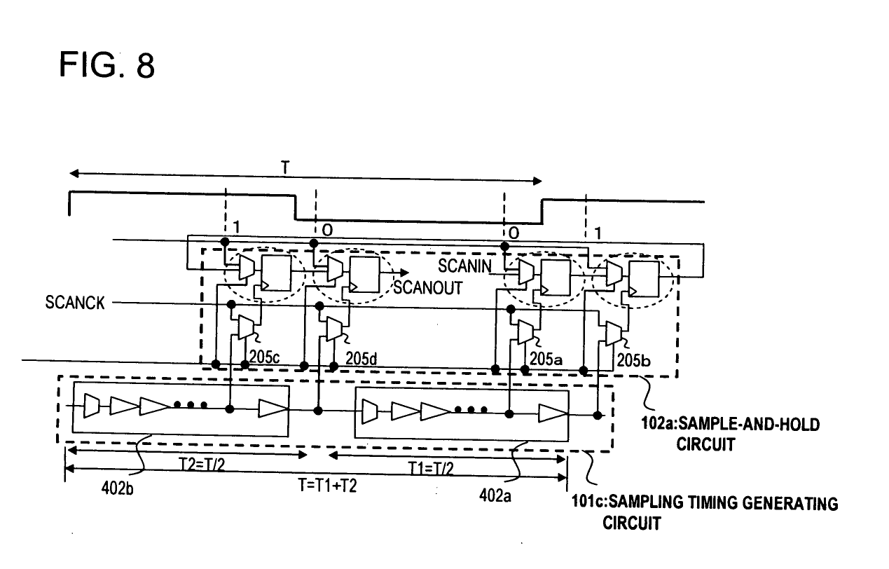

In this exemplary embodiment, the cascade relationship of the delay circuits 402a and 402b is changed and measurement is preformed twice. Specifically, the sampling is performed the first time with the delay line 402a serving as the initial stage of the sampling timing generating circuit 101c, as illustrated in FIG. 7. If the duty ratio is a normal value at this time, then the logic levels “1001” are output from the scan output SCANOUT. Sampling is performed the second time with the delay line 402b serving as the initial stage of the sampling timing generating circuit 101c, as illustrated in FIG. 8. This time, the logic levels “0110” are output from the scan output SCANOUT. The control circuit 103 controls the multiplexers Ma, Mb so as to change over the delay lines 402a, 402b, and controls the scan-shift operation.

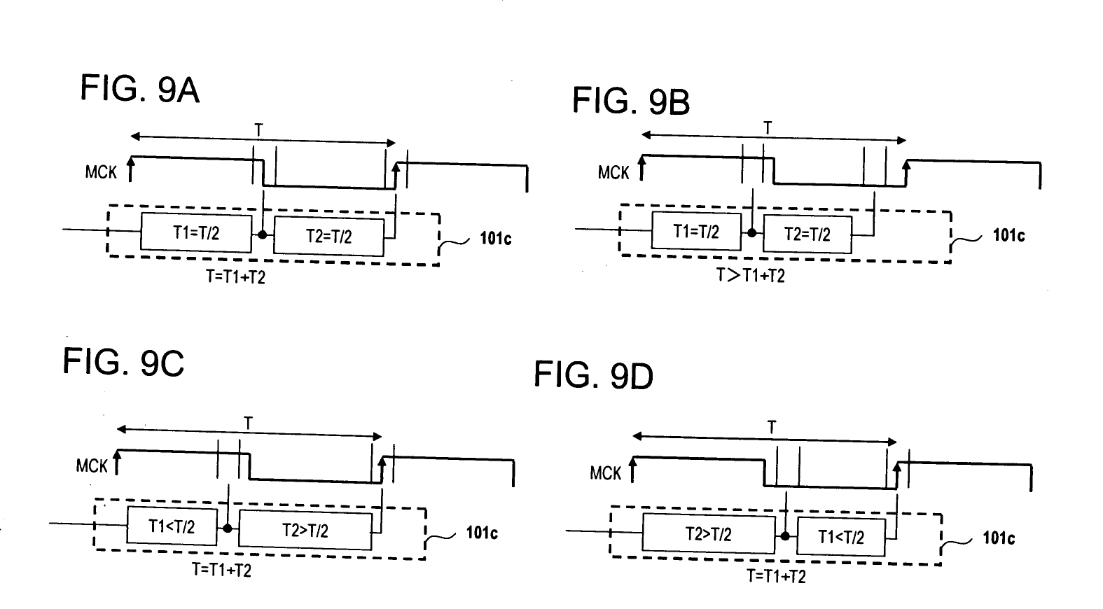

FIG. 9A is a timing chart in a normal case, in which the device is free of any variation. Assume that delay time in the delay lines 402a, 402b develops a variation owing to variation in the device. For example, assume that delay time shortens by (b−a)T/100 or more with respect to the period T of the measurement-target clock signal MCK. Owing to the fact that the period of the measurement-target clock signal MCK is maintained, the rising edge thereof is followed by the next rising edge after a time equivalent to the period T. However, since sampling timing shifts, as shown in FIG. 9B, the logic levels “0011” are output as the scan output SCANOUT and it will be understood that the measurement-target clock signal MCK cannot be sampled correctly because of device variation.

Next, assume that although the period T is maintained, the delay time of the delay line 402a becomes shorter than T/2 and the delay time of the delay line 402b becomes longer than T/2. In the case of measurement the first time, i.e., in the case where the delay line 402a is the initial stage of the delay lines, the logic levels “1011” are output as the scan output SCANOUT, as shown in FIG. 9C. In the case of measurement the second time, the logic levels “0010” are output as the scan output SCANOUT, as shown in FIG. 9D. It will be understood that the measurement-target clock signal MCK cannot be sampled correctly because of device variation.

In accordance with the test circuit having the configuration described above, measurement precision of the sampling timing generating circuit comprising the delay lines 402a, 402b can be improved by performing measurement twice by changing over the relationship of the cascade connection between the delay lines 402a, 402b.

### Fourth Exemplary Embodiment

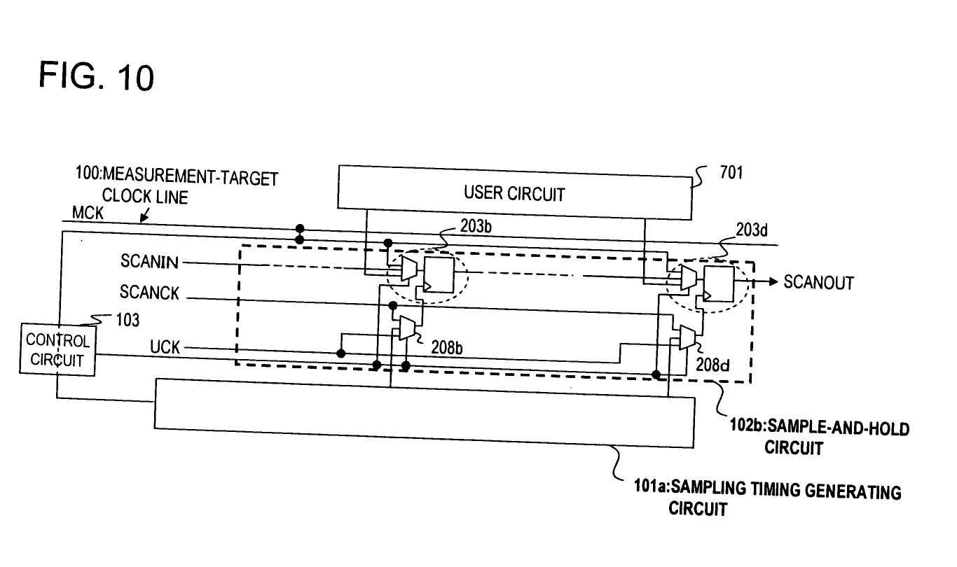

FIG. 10 is a circuit diagram of a test circuit according to a fourth exemplary embodiment of the present invention. Components in FIG. 10 identical with those shown in FIG. 2 are designated by like reference characters and need not be described again. The text circuit of FIG. 10 has a sample-and-hold circuit 102b in which the MUXSCANFFs 201a, 201b, 201c, 201d and the clock-signal selecting multiplexers 205a, 205b, 205c, 205d in the sample-and-hold circuit of the preceding exemplary embodiments are replaced by 3-input MUXSCANFFs 203a, 203b, 203c, 203d and 3-input multiplexers 208a, 208b, 208c, 208d, respectively.

With regard to the operation for testing the duty ratio of the measurement-target clock signal MCK, this exemplary embodiment is identical with the exemplary embodiments described thus far. Furthermore, this exemplary embodiment makes possible operation of a user circuit 701 based upon a user clock signal UCK and a scan-test operation of the user circuit 701 based upon a combination of the user clock signal UCK and scan clock signal SCANCK.

In accordance with the test circuit having the configuration described above, the circuitry can be simplified and an increase in the size of the circuitry suppressed by sharing the MUXSCANFFs with the user circuit.

### Fifth Exemplary Embodiment

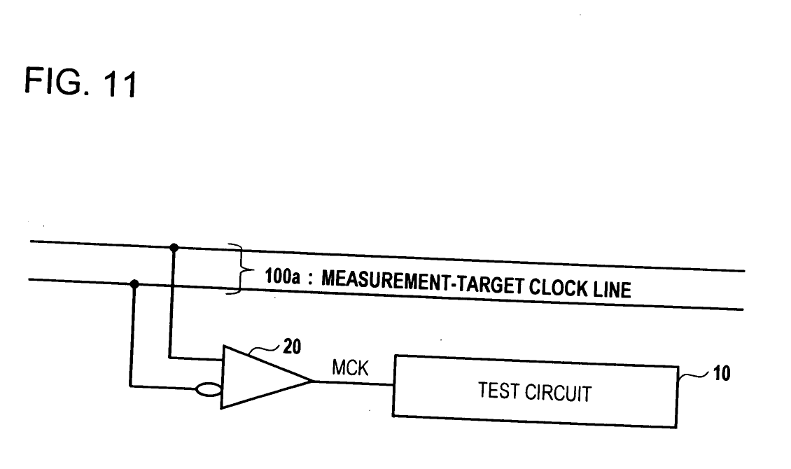

FIG. 11 is a circuit diagram of a test circuit according to a fifth exemplary embodiment of the present invention. This exemplary embodiment has a differential receiving circuit 20. The differential receiving circuit 20 is connected to the measurement-target clock line 100a, on which differential signals are transmitted, converts the differential signals to a single-phase clock signal and outputs the signal resulting from the conversion to a test circuit 10 as the measurement-target clock signal MCK. The test circuit 10 corresponds to the test circuits described in the first to fourth exemplary embodiments. By adopting this arrangement, even an LSI chip that uses differential clock signals can be tested for degradation of the duty ratio of the differential clock signals.

The disclosure of the patent document cited above is incorporated herein by thereto reference in this specification. Within the bounds of the full disclosure of the present invention (inclusive of the scope of the claims), it is possible to modify and adjust the modes and exemplary embodiments of the invention based upon the fundamental technical idea of the invention. Multifarious combinations and selections of the various disclosed elements are possible within the bounds of the scope of the claims of the present invention. That is, it goes without saying that the invention covers various modifications and changes that would be obvious to those skilled in the art within the scope of the claims.

What is claimed is:

1. A test circuit comprising:
a sampling timing generating circuit, to which a measurement-target clock signal is input, and outputs first and second sampling trigger signals at respective prescribed timings before and after a timing that is one-half period of the measurement-target clock signal after a first edge of the measurement-target clock signal; and
a sample-and-hold circuit that samples and holds the measurement-target clock signal in correspondence with respective ones of the first and second sampling trigger signals.

2. The circuit according to claim 1, wherein said sampling timing generating circuit outputs third and fourth sampling trigger signals at respective prescribed timings before and after the first edge; and
said sample-and-hold circuit samples and holds the measurement-target clock signal MCK further in correspondence with respective ones of the third and fourth sampling trigger signals.

3. The circuit according to claim 1, wherein said sample-and-hold circuit is included in a scan path.

4. The circuit according to claim 2, wherein said sample-and-hold circuit is included in a scan path.

5. The circuit according to claim 2, wherein said sample-and-hold circuit includes four registers that construct a scan-path register;
sampling values, which have been sampled at the first to fourth sampling trigger signals, being stored in respective ones of the corresponding registers.

6. The circuit according to claim 2, wherein said sampling timing generating circuit receives the measurement-target clock signal MCK as an input, generates a signal having a frequency that is double that of the measurement-target clock signal MCK and generates the first to fourth sampling trigger signals based upon the generated signal having double the frequency.

7. The circuit according to claim 5, wherein said sampling timing generating circuit includes:
a PLL circuit for receiving the measurement-target clock signal MCK as an input and generating the signal having double the frequency;
a delay circuit for delaying an output signal from said PLL circuit; and
a frequency dividing circuit for frequency-dividing the output signal from said PLL circuit and applying a prescribed delay;
said sampling timing generating circuit generating the first and third sampling trigger signals based upon the output signal from said PLL circuit and generates the second and fourth sampling trigger signals based upon an output signal from said delay circuit; and
said sample-and-hold circuit samples and holds the measurement-target clock signal MCK in correspondence with respective ones of the first and second sampling trigger signals when an output signal from said frequency dividing circuit is at a first logic level, and samples and holds the measurement-target clock signal MCK in correspondence with respective ones of the third and fourth sampling trigger signals when the output signal from said frequency dividing circuit is at a second logic level.

8. The circuit according to claim 2, wherein said sampling timing generating circuit comprises a multistage delay circuit that delays the measurement-target clock signal MCK received as an input thereto; the first to fourth sampling trigger signals being output from respective ones of prescribed positions in said delay circuit.

9. The circuit according to claim 2, wherein said sampling timing generating circuit comprises two sets of cascade-connected multistage delay circuits for delaying the measurement-target clock signal MCK received as an input thereto; and
said two sets of delay circuits are arranged in such a manner that the delay circuits in the cascade relationship are mutually interchangeable, the first and second sampling trigger signals are output from respective ones of prescribed positions in one of said delay circuits and the third and fourth sampling trigger signals are output from respective ones of prescribed positions in the other of said delay circuits.

10. The circuit according to claim 5, wherein said sample-and-hold circuit is adapted so as to make it possible to store an output of a user circuit in the register in response to a user clock signal.

11. The circuit according to claim 1, further comprising a differential receiving circuit for converting differential signals into a single-phase signal, wherein the single-phase signal obtained by the conversion is input as the measurement-target clock signal MCK.

12. The circuit according to claim 2, further comprising a differential receiving circuit for converting differential signals into a single-phase signal, wherein the single-phase signal obtained by the conversion is input as the measurement-target clock signal MCK.

13. The circuit according to claim 9, further comprising a differential receiving circuit for converting differential signals into a single-phase signal, wherein the single-phase signal obtained by the conversion is input as the measurement-target clock signal MCK.

14. A semiconductor device having the test circuit set forth claim 1.

15. A method of testing a semiconductor device, comprising:
inputting a measurement-target clock signal; and
sampling and holding the measurement-target clock signal at respective prescribed timings before and after a timing that is one-half period of the measurement-target clock signal after a first edge of the measurement-target clock signal.

16. The method according to claim 15, further comprising a step of outputting the sampled-and-held signal via a scan path.
